(19) United States
(12) Patent Application Publication
(10) Pub. No.: US 2025/0105377 A1
(43) Pub. Date: Mar. 27, 2025

(54) HOUSING FOR A BATTERY SYSTEM, BATTERY SYSTEM, ELECTRIC VEHICLE AND METHOD FOR DETECTING DAMAGE TO THE HOUSING

(71) Applicant: SAMSUNG SDI CO., LTD., Yongin-si (KR)

(72) Inventor: Florian Maxl, Graz (AT)

(21) Appl. No.: 18/799,395

(22) Filed: Aug. 9, 2024

(30) Foreign Application Priority Data
Sep. 21, 2023 (EP) 23198845.2

(51) Int. Cl. H01M 10/42; H01M 10/48; H01M 10/6554; H01M 50/224; H01M 50/242; H01M 50/249

(52) U.S. Cl. CPC H01M 10/4264; H01M 10/488; H01M 10/6554; H01M 50/224; H01M 50/242; H01M 50/249

(57) ABSTRACT

A housing for a battery system includes: an underbody structure including an upper portion and a lower portion; and a detection system for detecting damage to the underbody structure. The upper portion and the lower portion are electrically conductive and oppositely arranged at a distance from each other to be electrically isolated from each other and forming a capacitor therebetween. The detection system includes a resonant circuit into which the capacitor is interconnected is configured to apply a voltage to the resonant circuit at the resonance frequency of the resonant circuit and to detect a change in the capacitance by monitoring a change of the current at the resonance frequency.

### CROSS-REFERENCE TO RELATED APPLICATION

The present application claims priority to and the benefit of European Patent Application No. 23198845.2, filed on Sep. 21, 2023, in the European Patent Office, the entire disclosure of which is incorporated herein by reference.

### BACKGROUND

### 1. Field

Aspects of embodiments of the present disclosure relate to a housing for a battery system, a battery system including the housing, an electric vehicle including the battery system, and a method for detecting damage to the housing for a battery system.

### 2. Description of the Related Art

Recently, vehicles for transportation of goods and peoples have been developed that use electric power as a source for motion. Such an electric vehicle is an automobile that is propelled by an electric motor using energy stored in rechargeable (or secondary) batteries. An electric vehicle may be solely powered by batteries or may be a hybrid vehicle powered by, for example, a gasoline generator. Furthermore, the vehicle may include a combination of an electric motor and a conventional combustion engine.

Generally, an electric-vehicle battery (EVB, or traction battery) is a battery used to power the propulsion of battery electric vehicles (BEVs). Electric-vehicle batteries differ from starting, lighting, and ignition batteries in that they are designed to provide power for sustained periods of time. A rechargeable (or secondary) battery differs from a primary battery in that it is designed to be repeatedly charged and discharged, while the latter provides an irreversible conversion of chemical to electrical energy. Low-capacity rechargeable batteries are used as power supply for small electronic devices, such as cellular phones, notebook computers, and camcorders, while high-capacity rechargeable batteries are used as power supply for hybrid vehicles and the like.

Rechargeable batteries may be used as a battery module formed of a plurality of unit battery cells coupled to each other in series and/or in parallel to provide a high energy density, such as for motor driving of a hybrid vehicle. For example, the battery module may be formed by interconnecting the electrode terminals of the plurality of unit battery cells in an arrangement or configuration depending on a desired amount of power and to realize a high-power rechargeable battery.

Battery modules can be constructed in either a block design or a modular design. In the block design, each battery is coupled to a common current collector structure and a common battery management system, and the unit thereof is arranged in a housing. In the modular design, pluralities of battery cells are connected to form submodules, and several submodules are connected to form the battery module. In automotive applications, battery systems often consist of a plurality of battery modules connected to each other in series to provide a desired voltage. The battery modules may include submodules with a plurality of stacked battery cells, and each stack may include cells connected in parallel that are, in turn, connected in series (XpYs) or cells connected in series that are, in turn, connected in parallel (XsYp).

The mechanical integration of such a battery pack includes appropriate mechanical connections between the individual components (e.g., within battery modules and between them and a supporting structure of the vehicle). These connections should remain functional and safe throughout the average service life of the battery system. Further, installation space and interchangeability requirements must be met, especially in mobile applications.

Mechanical integration of battery modules may be achieved by providing a carrier framework and by positioning the battery modules thereon. Fixing the battery cells or battery modules may be achieved by fitted depressions in the framework or by mechanical interconnectors, such as bolts or screws. In other examples, the battery modules are confined by fastening side plates to lateral sides of the carrier framework. Moreover, cover plates may be fixed atop and below the battery modules.

The carrier framework of the battery pack is mounted to a carrying structure of the vehicle. When the battery pack is fixed at the bottom of the vehicle, the mechanical connection may be established from the bottom side by, for example, bolts passing through the carrier framework of the battery pack. The framework is generally made of aluminum or an aluminum alloy to lower the total weight of the construction.

Related art battery system, despite any modular structure, usually include a housing that acts as an enclosure to seal the battery system against the environment and provides structural protection of the battery system's components. Housed battery systems are generally mounted as a whole into their application environment, such as an electric vehicle. Thus, the replacement of defective system parts, for example, a defective battery submodule, first requires dismounting the entire battery system and removal of the housing. Even small defects or replacement of relatively cheap system parts may require dismounting of the entire battery system and its separate repair and reinstallation. Because high-capacity battery systems are expensive, large, and heavy, such a procedure is burdensome and the storage of the bulky battery systems, such as in the mechanic's workshop, is difficult.

Battery systems generally have voltage sources at a hazardous or dangerous voltage level. Misuse of the battery system or deformations of the housing thereof, such as those caused by external forces exerted on the underbody of the battery system during collisions or by material fatigue, may lead to dielectric breakdown. Dielectric breakdown can cause a fire or even an explosion inside the battery system.

### SUMMARY

The present disclosure is defined by the appended claims and their equivalents. The description that follows is subject to this limitation. Any disclosure lying outside the scope of the claims and their equivalents is intended for illustrative as well as comparative purposes.

According to an embodiment of the present disclosure, a housing for a battery system includes an underbody structure and a detection system for detecting damage to the underbody structure. The underbody structure includes an upper portion and a lower portion that are electrically conductive and oppositely arranged at a distance from each other to be electrically isolated from each other and forming a capacitor therebetween. The detection system includes a resonant circuit into which the capacitor is interconnected and is configured to apply a voltage to the resonant circuit at the resonance frequency of the resonant circuit and to detect the change in the capacitance by monitoring a change in the current at the resonance frequency.

According to another embodiment of the present disclosure, a battery system includes the above-described housing and a plurality of battery cells accommodated within the housing.

Yet another embodiment of the present disclosure provides an electric vehicle including the above-described battery system.

Yet another embodiment of the present disclosure refers to a method for detecting damage to an underbody structure of a housing for a battery system as described above. According to the method, a voltage is applied to the resonant circuit at the resonance frequency of the resonant circuit, and a change in the capacitance is detected by monitoring a change in the current at the resonance frequency.

Further aspects and features of the present disclosure can be learned from the dependent claims and/or the following description.

### BRIEF DESCRIPTION OF THE DRAWINGS

Aspects and features of the present disclosure will become apparent to those of ordinary skill in the art by describing, in detail, embodiments thereof with reference to the attached drawings, in which:

FIG. 1 is a cross-sectional view of a battery system including a housing according to an embodiment,

FIG. 2 is a schematic phase-current-diagram of a resonance circuit,

FIG. 3 is a cross-sectional view of a battery system including a housing according to an embodiment, and

FIG. 4 is a flow diagram describing a method for detecting damage to an underbody structure of a housing for a battery system according to an embodiment.

### DETAILED DESCRIPTION

Reference will now be made, in detail, to embodiments, examples of which are illustrated in the accompanying drawings. Aspects and features of the present disclosure, and implementation methods thereof, will be described with reference to the accompanying drawings. The present disclosure may, however, be embodied in various different forms and should not be construed as being limited to the embodiments illustrated herein. Rather, these embodiments are provided as examples so that this disclosure will be thorough and complete and will fully convey the aspects and features of the present disclosure to those skilled in the art.

Accordingly, processes, elements, and techniques that are not considered necessary for those having ordinary skill in the art to have a complete understanding of the aspects and features of the present disclosure may not be described.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly. Herein, the terms “upper” and “lower” are defined according to the z-axis in the drawings. For example, an upper portion is positioned at the upper part of the z-axis, and a lower portion is positioned at the lower part thereof.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

According to one embodiment of the present disclosure, a housing for a battery system including an underbody structure and a detection system for detecting damage to the underbody structure is provided. The underbody structure includes an upper portion and a lower portion, which are electrically conductive and oppositely arranged at a distance from each other to be electrically isolated from each other to form a capacitor. The detection system includes a resonant circuit into which the capacitor is interconnected. The detection system is further configured to apply a voltage to the resonant circuit at the resonance frequency of the resonant circuit and to detect a change in the capacitance by monitoring a change in the current at the resonance frequency. The resonant frequency is defined as the frequency at which the impedance of the circuit is at a minimum.

Thus, damage to the underbody structure can be detected by indirectly measuring the distance (and changes thereof), in the z-axis direction, between the upper portion and the lower portion of the underbody structure of the housing by using a resonant circuit. If the capacity (or capacitance) of the capacitor changes due to deformation of the upper portion and/or the lower portion of the underbody structure, the resonant frequency of the circuit changes such that the current flowing at the applied voltage at the (initial) resonance frequency, that is, the resonance frequency of the circuit before the deformation occurred, drops significantly. The drop of the current at the (initial) resonance frequency is detected and considered to be indicative of damage having occurred to the underbody structure. The voltage is applied at the (initial) resonance frequency because, at the resonance frequency, the highest current peaks are provided, thereby facilitating the measurements thereof. In summary, embodiments of the present disclosure exploit that damage to the underbody structure causes a change in the distance between the two halves of the capacitor, thereby changing the capacitance of the capacitor and the resonance frequency of the resonant circuit so that the current at the initial or former resonance frequency changes as well. Thus, a detected change in the current indicates damage to the underbody structure. Accordingly, a driver or technician, etc., can be quickly notified of damage to the underbody structure of a housing for a battery system.

According to one embodiment, the detection system may be configured to determine a degree of damage to the underbody structure based on the detected change of the capacitance. For example, the detection system may be configured to determine a degree of damage to the underbody structure based on a detected change in the current at the (initial) resonance frequency during monitoring thereof. Based on the determined degree of damage to the underbody structure, different countermeasures may be taken. Accordingly, the detected damage to the underbody structure may be classified into different categories, such as slightly damaged, moderately damaged, and seriously damaged, for example.

The detection system may include a memory unit and may be configured to store the degrees of damage to the underbody structure determined over time on the memory unit and to determine an expected remaining service life of the underbody structure based on the stored determined degrees of damage over time. The memory unit may store historical data about different degrees of damage to underbody structures correlated with expected remaining service lives or lifespans. Further, statements can be made about whether and when maintenance of the battery system or the housing for the battery system should be sought or is necessary to prevent dangerous dielectric breakdowns, for example.

Furthermore, the detection system may be configured to generate a warning signal if the determined degree of damage to the underbody structure exceeds a reference (or predetermined) damage threshold and/or based on the determined remaining expected service life of the underbody structure drops below a reference (or predetermined) service life threshold. For example, the reference damage threshold may correspond to a parameter at which the distance between the upper portion and the lower portion of the underbody structure is reduced below about 75 percent, below about 50 percent, or below about 25 percent of its initial distance. The reference service life threshold may correspond to a parameter at which the next maintenance date or inspection date is intended. Accordingly, when the expected remaining service life of the underbody structure is shorter than the time period to the next maintenance date, a warning signal is generated to indicate the severity of the condition of the underbody structure.

Moreover, the detection system may include an interface. In such an embodiment, the detection system may be configured to output the determined degree of damage to the underbody structure, the determined remaining expected service life of the underbody structure, and/or the generated warning signal via the interface. The interface may be connected to a battery management system (BMS) of the battery system and/or to a control unit of the vehicle. The interface may be further directly or indirectly connected to a display and/or to loudspeakers in the vehicle to inform the driver of the vehicle about the condition of the underbody structure.

According to another embodiment, the housing may further include an underbody protective plate and a cooler plate thermally connectable to (or thermally connected to) the battery cells disposed in the housing. The upper portion may form at least a part of the cooler plate of the housing, and/or the lower portion may form at least a part of the underbody protective plate. Because housings for battery systems usually include an underbody protective plate and a cooler plate, the detection of the capacitance of the capacitor according to embodiments of the present disclosure may be performed without requiring additional assembly space.

According to another embodiment, the housing may further include an underbody protective plate and a cooler plate thermally connectable to the battery cells disposed in the housing. The upper portion and the lower portion may be arranged between the underbody protective plate and the cooler plate.

According to another embodiment, the upper portion and/or the lower portion may include a metal foil and/or a metal coating. The metal foil and/or the metal coating may include (or may consist of) aluminum or an alloy thereof. Aluminum is known to exhibit good conductivity and good durability and is readily available.

According to another embodiment, the underbody structure may include an air cushion film arranged between the upper portion and the lower portion. For example, the underbody structure may an air cushion film having a double-sided aluminum coating. For example, the upper portion and the lower portion form the aluminum coatings of the air cushion film. Air cushion films with double-sided aluminum coatings are widely available at relatively low cost.

According to another embodiment, the housing may be sealable, and the upper portion and/or the lower portion may form a part of the sealing structure. For example, the upper portion and/or the lower portion may be at least a part of the cooling plate and/or the underbody protective plate forming a part of the sealing structure. Accordingly, a compact design may be achieved.

According to another embodiment, the resonant circuit may include a resistor (R), an inductor (L), and the capacitor (C) forming an RLC-circuit. The three components RLC are all in series or in parallel with the voltage source to form a series RLC-circuit or a parallel RLC-circuit. All three elements in series or all three elements in parallel are the simplest in concept and the most straightforward to analyze.

According to another embodiment, the detection system may be configured to determine a capacitance value of the capacitor and to determine a degree of damage to the underbody structure based on the determined capacitance value. The capacitance value of the capacitor may be directly measured by the detection system. In such an embodiment, the damage to the underbody structure is detected redundantly, thereby increasing the reliability of the determined degree of damage to the underbody structure.

Optional features described with respect to one embodiment of the present disclosure may be interchangeably used for or with other embodiments of the present disclosure, and the aspects and features described with the optional feature(s) analogously applies. A recurring description thereof is therefore omitted.

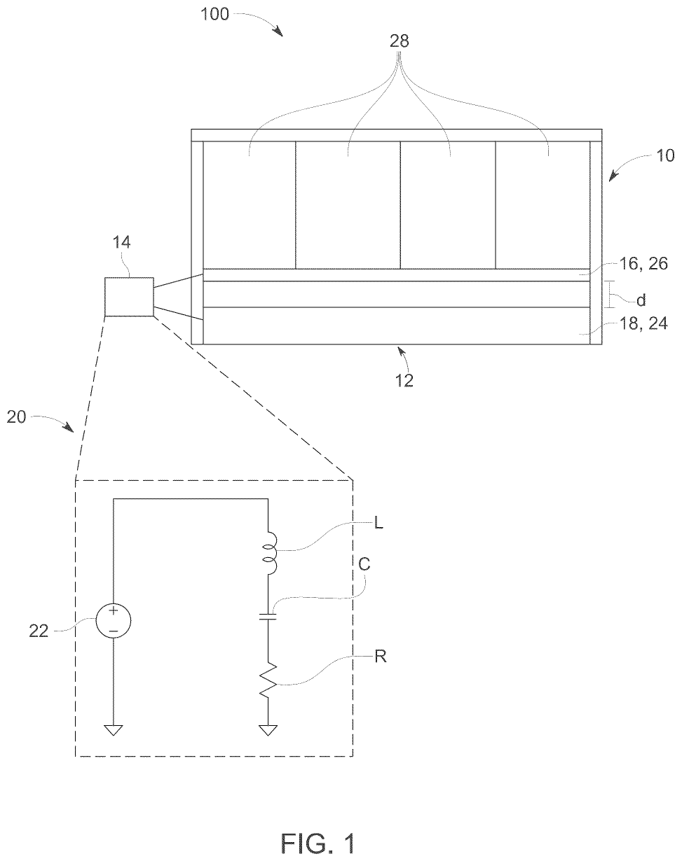

FIG. 1 is a cross-sectional view of a battery system 100 including a housing 10 according to an embodiment.

The housing 10 includes an underbody structure 12 and a detection system 14 for detecting damage to the underbody structure 12. The housing 10 may include side walls and a top cover such that the underbody structure 12, the side walls, and the top cover together form an enclosure sealing the battery system 100 against the environment and providing structural protection to the components of the battery system 100, for example, to a plurality of battery cells 28 disposed in the housing 10, as shown in, for example, FIG. 1. Such a housed battery system 100 is generally mounted as a whole into their application environment, such as an electric vehicle. Therefore, the condition of the underbody structure 12 of the housing 10 of the battery system 100 is generally unknown in the mounted state.

The underbody structure 12 includes an upper portion 16 and a lower portion 18, which are electrically conductive and oppositely arranged at a distance d from each other to be electrically isolated from each other but such that a capacitor C is formed by the upper portion 16 and the lower portion 18. The upper portion 16 and the lower portion 18 are arranged in parallel such that the distance d is substantially constant over (or across) the area of the capacitor.

As commonly known, the capacitance C of a capacitor is given by the surface area A of the plates, the distance d between the plates, and the permittivity ∈₀·∈ᵣ of the material between the plates as shown in the following equation:

$$C = {ϵ}_{0} \cdot {ϵ}_{r} \cdot \frac{A}{d}$$

Hence, the capacitance C of the capacitor C changes when the distance d between the plates changes. Thus, if the lower portion 18 of the underbody structure 12 is deformed by a misuse of the battery system 100, by external forces exerted thereon during collisions, or by general material fatigue, the distance d will change such that the capacitance C of the capacitor C will change as well. The battery system 100 generally has voltage sources at hazardous voltage levels such that a reduction of the distance d may lead to a dielectric breakdown, which is critical because it may cause a fire or even an explosion inside of the battery system 100. Therefore, embodiments of the present disclosure provide a solution for overcoming the disadvantage of not knowing the condition of the underbody structure 12 of the housing 10 of the battery system 100.

As shown in the enlarged insert of FIG. 1, the detection system 14 includes a resonant circuit 20 into which the capacitor C, formed by the upper portion 16 and the lower portion 18 of the underbody structure 12, is interconnected. The resonant circuit 20 further includes a resistor R and an inductor L to form an RLC-circuit. The resistor R, the inductor L, and the capacitor C are connected together in series, but they are not limited to this connection structure. For example, in other embodiments, the resistor R, the inductor L, and the capacitor C may be connected in parallel or an arbitrary combination thereof. An arrangement with all three elements R, L, C in series or in parallel is, however, the simplest in concept and the most straightforward to analyze.

The detection system 14 is configured to apply a voltage to the resonant circuit 20 at the resonance frequency of the resonant circuit 20 and to detect a change in the capacitance of the capacitor C by monitoring a change in the current at the resonance frequency. The current value and its change may be measured by an Ampere meter (also referred to as an ammeter) 22 connected in series as depicted in FIG. 1.

The detection system 14 may be attached to the housing 10, for example, to one of the side walls or to the underbody structure 12. For example, the detection system 14 may be attached to an inner surface of the housing 10 directed (or facing) inwardly or to an outer surface of the housing 10 directed to (or facing) the outside. The detection system 14 may include a printed circuit board (PCB) on which the resistor R, the inductor L, and the Ampere meter 22 are provided. The PCB is electrically connected to the capacitor C. Furthermore, the housing 10 may have a recess configured to receive (e.g., completely receive) the detection system 14 (e.g., the PCB), and the detection system 14 may be received in (e.g., accommodated in) the recess in a space saving and compact manner.

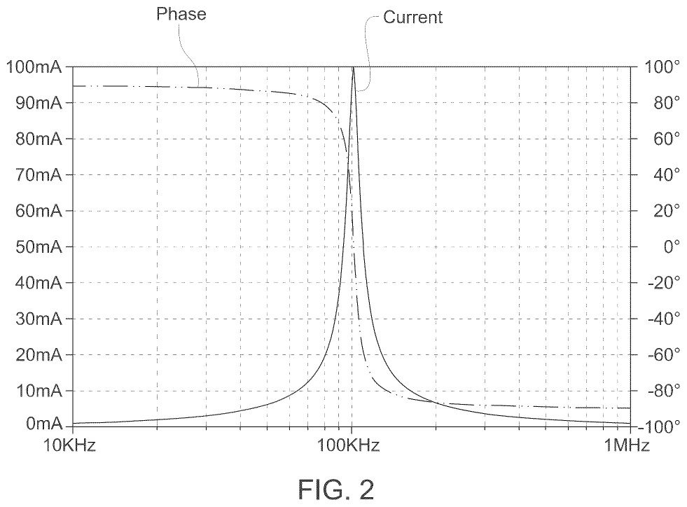

FIG. 2 is a schematic phase-current-diagram over frequency of an resonance circuit 20 according to an embodiment of the present disclosure in which the resistor R, the inductor L, and the capacitor C are all connected in series with the voltage source (a so-called series RLC-circuit). For the sake of better comprehensibility, values of the parameters are shown at the coordinate axes. The resonance frequency is 100 KHz and the maximum current at the resonance frequency is 100 mA. However, these values are merely examples, and the present disclosure is not limited thereto. It is to be understood that the resonance frequency of the resonant circuit 20 depends on its particular design and implementation. The diagram shown in FIG. 2 generally illustrates the behavior of the current in the resonant circuit 20 over voltages applied at different frequencies. When the voltage is applied at the resonance frequency of the resonance circuit 20, the highest current value may be detected.

If the capacity (or capacitance) of the capacitor C changes due to deformation of the upper portion 16 and/or the lower portion 18 of the underbody structure 12, the resonant frequency of the resonant circuit 20 changes correspondingly, for example, the maximum current peak shifts towards higher or lower frequencies, such that the current flowing at the applied voltage at the initial or former resonance frequency, that is, the resonance frequency of the resonance circuit 20 prior to the deformation, drops significantly. This drop in the current at the initial resonance frequency is detected via the Ampere meter 22 and can be considered as indicative of damage having occurred to the underbody structure 12. Thus, because damage to the underbody structure 12 causes a change of the distance d of the capacitor C, the capacitance of the capacitor C and the resonance frequency of the resonant circuit 20 change so that the current at the initial or former resonance frequency changes as well. That is, the detected change of the current at the resonance frequency indicates damage to the underbody structure 12.

FIG. 1 further depicts that the housing 10, according to an embodiment of the present disclosure, includes an underbody protective plate 24 and a cooler plate 26 thermally connectable or connected to a plurality of battery cells 28 disposed in the housing 10. According to the illustrated embodiment, the upper portion 16 forms the cooler plate 26 of the housing 10, and the lower portion 18 forms the underbody protective plate 24. Thus, the detection of the capacitance of the capacitor C according to this embodiment may be performed without adding a separate capacitor C, thereby saving assembly space.

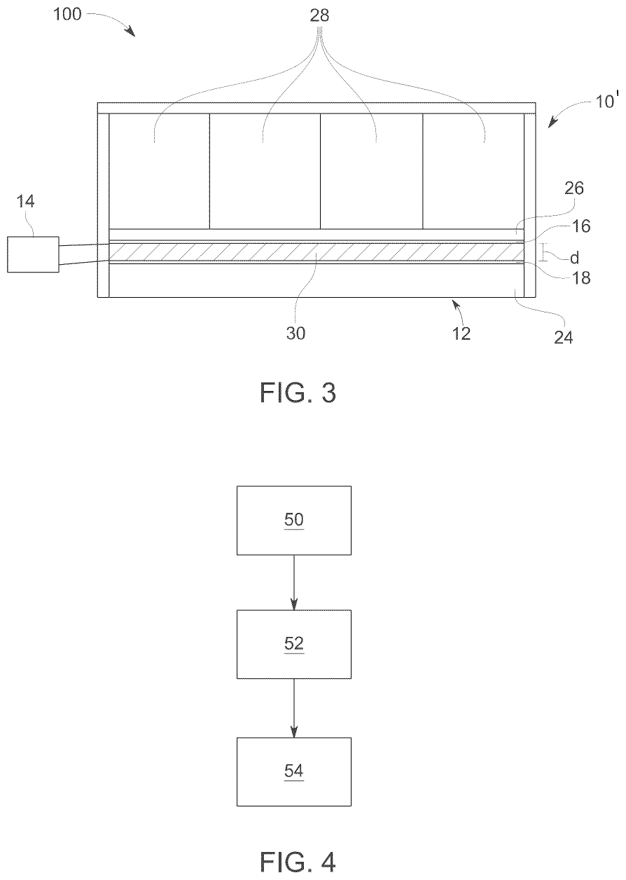

FIG. 3 is a cross-sectional view of a battery system 100 including a housing 10′ according to another embodiment. The housing 10′ according to the illustrated embodiment differs from the housing 10 of FIG. 1 in that the upper portion 16 and the lower portion 18 of the housing 10′ do not form (or are not) the cooler plate 26 and the underbody protective plate 24. In other words, the cooler plate 26 and the underbody protective plate 24 are not used to implement (e.g., are not a part of or do not form) the capacitor C in this embodiment. Other aspects and features described with respect to the housing 10 shown in FIG. 1 may be interchangeably used for the housing 10′ shown in FIG. 3.

According to the embodiment shown in FIG. 3, the upper portion 16 and the lower portion 18 of the underbody structure 12 of the housing 10′ are arranged between the underbody protective plate 24 and the cooler plate 26. Thus, the upper portion 16 and the lower portion 18 form a capacitor C arranged between the underbody protective plate 24 and the cooler plate 26 and interconnected into the resonant circuit 20 as described above with respect to FIG. 1. The upper portion 16 and the lower portion 18 of the underbody structure 12 are separated and electrically isolated from the underbody protective plate 24 and the cooler plate 26.

The upper portion 16 and the lower portion 18 may include a metal foil or a metal coating. For example, in view of the embodiment shown in FIG. 1, the upper portion 16 and the lower portion 18 may be formed as (or formed of) metal foil or metal coating attached to the underbody protective plate 24 and the cooler plate 26 such that the upper portion 16 and the lower portion 18 merely partially form the underbody protective plate 24 and the cooler plate 26. The metal is aluminum or an alloy including aluminum. Aluminum is lightweight and known to exhibit good conductivity and good durability and to be readily available.

In the embodiment shown in FIG. 3, the underbody structure 12 includes an air cushion film 30 arranged between the upper portion 16 and the lower portion 18. The air cushion film 30 provides decent electrical isolation. For example, the underbody structure 12 includes a double-sided aluminum coating of an air cushion film. For example, the upper portion 16 and the lower portion 18 form (or are formed as) the aluminum coatings deposited on the air cushion film 30. Such air cushion film with double-sided aluminum coatings is widely available at low cost.

FIG. 4 is a flow diagram describing a method for detecting damage to an underbody structure of a housing for a battery system such as the above-described underbody structure 12 of the housing 10, 10′ for the battery system 100. Aspects and features described above with respect to the housing 10 shown in FIG. 1 or the housing 10′ shown in FIG. 3 may be interchangeably used for the method to be described hereinafter.

According to a first step 50, the housing 10, 10′ for a battery system 100 according to an above-mentioned embodiment is provided.

According to a second step 52, a voltage is applied to the resonant circuit 20 at the resonance frequency of the resonant circuit 20.

According to a third step 54, a change in the capacitance of the capacitor C is detected by monitoring a change of the current at the resonance frequency.

Some Reference Symbol

| | | | |
|---|---|---|---|
| 10, 10′ | housing | 12 | underbody structure |
| 14 | detection system | 16 | upper portion |
| 18 | lower portion | 20 | resonant circuit |
| 22 | Ampere meter | 24 | underbody protective plate |
| 26 | cooler plate | 28 | battery cells |
| 30 | air cushion film | 50 | first method step |
| 52 | second method step | 54 | third method step |
| d | distance | C | capacitor |
| R | resistor | L | inductor |

What is claimed is:

1. A housing for a battery system comprising:
an underbody structure comprising:
an upper portion; and
a lower portion, the upper portion and the lower portion being electrically conductive and oppositely arranged at a distance from each other to be electrically isolated from each other and forming a capacitor therebetween; and
a detection system for detecting damage to the underbody structure, the detection system comprising a resonant circuit into which the capacitor is interconnected, and wherein the detection system is configured to apply a voltage to the resonant circuit at the resonance frequency of the resonant circuit and to detect a change in the capacitance by monitoring a change of the current at the resonance frequency.

2. The housing as claimed in claim 1, wherein the detection system is configured to determine a degree of damage to the underbody structure based on the detected change in the capacitance.

3. The housing as claimed in claim 2, wherein the detection system is configured to generate a warning signal based on the determined degree of damage to the underbody structure exceeding a damage threshold.

4. The housing as claimed in claim 3, wherein the detection system comprises an interface, and
wherein the detection system is configured to output a generated warning signal via the interface.

5. The housing as claimed in claim 2, wherein the detection system comprises an interface, and
wherein the detection system is configured to output the determined degree of damage to the underbody structure via the interface.

6. The housing as claimed in claim 2, wherein the detection system comprises a memory unit, and
wherein the detection system is configured to:
store degrees of damage to the underbody structure determined over time on the memory unit; and
determine an expected remaining service life of the underbody structure based on the stored determined degrees of damage over time.

7. The housing as claimed in claim 6, wherein the detection system is configured to generate a warning signal based on the determined remaining expected service life of the underbody structure dropping below a service life threshold.

8. The housing as claimed in claim 7, wherein the detection system comprises an interface, and
wherein the detection system is configured to output a generated warning signal via the interface.

9. The housing as claimed in claim 6, wherein the detection system comprises an interface, and
wherein the detection system is configured to output the determined remaining expected service life of the underbody structure via the interface.

10. The housing as claimed in claim 1, further comprising:
an underbody protective plate; and
a cooler plate thermally connectable to battery cells accommodated in the housing,
wherein the upper portion forms at least a part of the cooler plate of the housing, and
wherein the lower portion forms at least a part of the underbody protective plate.

11. The housing as claimed in claim 1, further comprising:
an underbody protective plate; and
a cooler plate thermally connectable to battery cells accommodated in the housing,
wherein the upper portion and the lower portion are arranged between the underbody protective plate and the cooler plate.

12. The housing as claimed in claim 1, wherein the upper portion and/or the lower portion comprise a metal foil and/or a metal coating.

13. The housing as claimed in claim 1, wherein the underbody structure comprises an air cushion film arranged between the upper portion and the lower portion.

14. The housing as claimed in claim 1, wherein the housing is sealable, and wherein the upper portion and/or the lower portion form a part of a sealing structure sealing the housing.

15. The housing as claimed in claim 1, wherein the resonant circuit comprises a resistor, an inductor, and the capacitor forming an RLC-circuit.

16. The housing as claimed in claim 1, wherein the detection system is configured to determine a capacitance value of the capacitor and to determine a degree of damage to the underbody structure based on the determined capacitance value.

17. A battery system comprising:
the housing as claimed in claim 1; and
a plurality of battery cells accommodated within the housing.

18. An electric vehicle comprising the battery system as claimed in claim 17.

19. A method for detecting damage to the underbody structure of the housing for a battery system as claimed in claim 1, the method comprising:
applying a voltage to the resonant circuit at the resonance frequency of the resonant circuit; and
detecting a change in the capacitance by monitoring a change in the current at the resonance frequency.
